(19) United States
(12) Patent Application Publication
(10) Pub. No.: US 2003/0155623 A1
(43) Pub. Date: Aug. 21, 2003

(54) Semiconductor light receiving device

(76) Inventor: Masanobu Kato, Hokkaido (JP)

Correspondence Address: WENDEROTH, LIND & PONACK, L.L.P., 2033 K STREET N. W., SUITE 800, WASHINGTON, DC, 20006-1021, US

(21) Appl. No.: 10/294,576

(22) Filed: Nov. 15, 2002

(30) Foreign Application Priority Data
Feb. 19, 2002 (JP) 041721/2002

(51) Int. Cl. H01L 27/14; H01L 31/00

(52) U.S. Cl. 257/431

(57) ABSTRACT

A semiconductor light receiving device refracts light input from the side direction of the device so that refracted lights reach light receiving sections formed on the top of a semiconductor substrate. The device includes the light receiving sections, a light receiving surface formed on an inclined surface crossing the back and sides of the semiconductor substrate and a reflection film, formed opposite to the light receiving surface, for reflecting at least a part of the light having plural wavelengths. The light receiving surface has different refraction angles according to the wavelengths of the input light and demultiplexes the input light wavelength by wavelength. The reflection film is formed on a recessed surface crossing the back and sides of the semiconductor substrate and reflects light at a reflection angle which differs according to the wavelength so that the input light is more easily demultiplexed into lights which reach the respective light receiving sections.

### BACKGROUND OF THE INVENTION

The present invention relates to a semiconductor light receiving device for optical communications of a 1-μm band, particularly, for a WDM system, which need not use a wavelength filter or PLC and can be coupled directly to an optical fiber.

Due to the recent demands of larger capacity optical communications, WDM (Wavelength Division Multi/demultiplexing) systems have been developed actively and have been made into practical use. WDM systems transfer light having a plurality of wavelengths in a single optical fiber. Generally, the WDM systems employ a method which simultaneously inputs light with a wavelength of 1.3 μm and a wavelength of 1.55 μm into a single optical fiber or a method which separates the 1.5-μm band into an S band, C band and L band, further separates light of each band into intervals of 0.8 nm and then transfers the separated lights in a multiplexed form.

As described in 1998 IEEE Society Conference C-3-110, “1.3/1.55 μm WDM Optical Module for Simultaneous Transmission and Reception Using PLC Platform” by Toshikazu Hashimoto, et al., the first method of simultaneously inputting light with wavelengths of 1.3 μm and 1.55 μm into a single optical fiber needed to separately receive light of 1.3 μm and light of 1.55 μm, sent through a single optical fiber, a wavelength selection filter was provided on an optical waveguide where an optical circuit would be constituted and before a light receiving device to separate input light into lights with desired wavelengths, which would in turn be received at photodiodes (PDs) or the light receiving device.

As described in 1998 IEEE Society Conference C-3-137, “PLC Device for DWDM Systems” by Hisato Uetsuka, et al., the second method of separating the 1.5-μm band into S, C and L bands and performing wavelength multiplexed transmission requires PLCs (Planar Lightwave Circuits) to demultiplex light, sent through a single optical fiber, wavelength (channel) by wavelength. A PLC is an application-specific waveguide type optical circuit device formed on a silicon planar substrate.

FIG. 1 shows a schematic perspective view of the second method. A WDM optical fiber 11 is connected to a planar waveguide 13 which can transfer optical signals. The light that has been sent through the optical fiber 11 is demultiplexed into lights of individual wavelengths by a diffraction grating 12 formed on the planar waveguide 13. The demultiplexed lights of the individual wavelengths travel toward the respective light receiving sections and enter PDs wavelength by wavelength so that optical signals are converted to electrical signals. This prior art uses a PD array 14 which is an array of connected PDs corresponding to the individual wavelengths.

Depending on the direction of input light, there are three types of PDs, namely, a top incident type, back incident type and side (edge) incident type. Generally used are the top incident type and back incident type, which cause input light to be incident on a semiconductor substrate from the perpendicular direction. By way of contrast, as input light is incident on the side incident type light receiving device from the side thereof, an optical fiber can be attached to the light receiving device mounted on the substrate from the horizontal direction at the time the light receiving device is mounted together with another device on the substrate to form a module. This facilitates the mounting process. Such a side incident type device changes an optical path by refraction or reflection of input light in the device and receives the input light at the light receiving sections formed on the top and back of the device.

In the case of the side incident type light receiving device, because an inclined surface is formed as a light receiving surface on one side by etching, the input light is refracted at the inclined light receiving surface and is input to light receiving sections formed on the top or back of the semiconductor substrate. In such a structure, the positional alignment of the position of the inclined surface with the position of each light receiving section is very important and it is necessary to carefully align the positions while observing both sides of a wafer using a double sided aligner.

In case where lights with wavelengths of 1.3 μm and 1.55 μm are simultaneously input into a single optical fiber, the insertion of the wavelength selection filter raises such a problem that the light receiving sensitivity of the PDs is lowered. Further, the use of the wavelength selection filter requires the manufacturing cost for the filter and the cost for processing the optical waveguide. In addition, the method of separating the 1.5-μm band into individual bands and performing wavelength multiplexed transmission has such a problem that PLCs which demultiplex light wavelength by wavelength and perform wavelength multiplexed transmission have a low yield and are thus extremely expensive at present and that the PD array itself has a low yield. As a result, the device as a whole becomes very expensive.

### SUMMARY OF THE INVENTION

The invention has been devised in view of the problems of the light receiving systems that use the conventional semiconductor light receiving devices, and aims at providing a novel and improved semiconductor light receiving device which overcomes the problems of a reduction in the light receiving sensitivity of a PD caused by the use of a wavelength selection filter and a cost increase caused by the use of a wavelength selection filter and a PLC, and requires neither a wavelength selection filter nor PLC and can be coupled directly to an optical fiber.

To achieve the object, a semiconductor light receiving device of the present invention need not use a wavelength selection filter or PLC, can be coupled directly to an optical fiber and contributes to cost reduction. The device refracts light input from the side direction of the device so that refracted lights reach light receiving sections formed on the top of a semiconductor substrate. The device includes the light receiving sections, a light receiving surface formed on an inclined surface crossing the back and sides of the semiconductor substrate and a reflection film, formed opposite to the light receiving surface, for reflecting at least a part of the light having plural wavelengths. The light receiving surface has different refraction angles according to the wavelengths of the input light and demultiplexes the input light wavelength by wavelength. The reflection film is formed on a recessed surface crossing the back and sides of the semiconductor substrate and reflects light at a reflection angle which differs according to the wavelength so that the input light is more easily demultiplexed into lights which reach the respective light receiving sections.

### BRIEF DESCRIPTION OF THE DRAWINGS

FIG. 1 is a schematic perspective view of a semiconductor light receiving substrate according to the prior art;

FIG. 2 is a cross-sectional view of a semiconductor light receiving device according to a first embodiment of the invention;

FIG. 3 is a cross-sectional view of a semiconductor light receiving device according to a second embodiment of the invention;

FIG. 4 is a cross-sectional view of a semiconductor light receiving device according to a third embodiment of the invention;

FIG. 5 is a cross-sectional view of a semiconductor light receiving device according to a fourth embodiment of the invention;

FIG. 6 is a cross-sectional view of a semiconductor light receiving device according to a fifth embodiment of the invention;

FIG. 7 is a cross-sectional view of a semiconductor light receiving device according to a sixth embodiment of the invention; and

FIG. 8 is a cross-sectional view of a semiconductor light receiving device according to a seventh embodiment of the invention.

### DETAILED DESCRIPTION OF THE PREFERRED EMBODIMENTS

Preferred embodiments of a fabrication method for a semiconductor device according to the invention will be described below referring to the accompanying drawings. To avoid the redundant description, like or same reference numerals are given to those components which have substantially the same functional structures through the present specification and the accompanying drawings.

(First Embodiment)

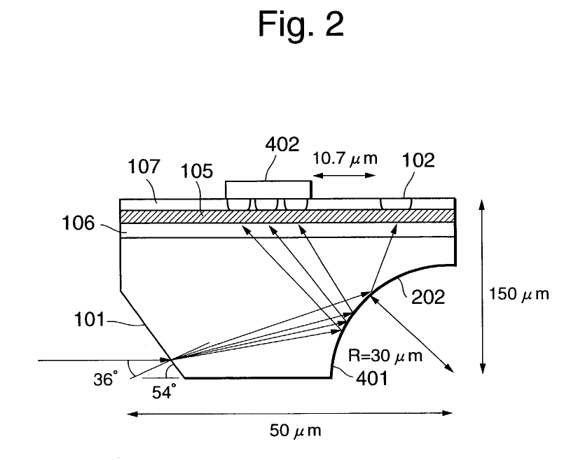

FIG. 2 presents a cross-sectional view of the first embodiment of the invention. The cross-sectional view also shows optical paths for individual input lights. The first embodiment is a side incident type light receiving device which uses a recessed surface as a reflection surface located opposite to the light receiving surface. Indium phosphorus (InP), gallium arsenic (GaAs) or amorphous silicon or the like is used for a semiconductor substrate 104, and a III-V mixed crystal layer, such as an indium gallium arsenic (InGaAs) layer, an indium gallium arsenic phosphorus (InGaAsP) layer, an indium gallium aluminum arsenic (InGaAlAs) layer or an indium arsenic phosphorus (InAsP) layer, is used for a light absorption layer 105.

An n-InP layer as a bottom layer 106, the light absorption layer 105 and an n-InP layer as a top layer 107 are epitaxially grown on the semiconductor substrate 104 in order. Further, a p-InP portion is selectively diffused in the top n-InP layer 107 to form a pn junction, thereby forming a 1.3-μm light receiving section 102 and a 1.5-μm band receiving section 402. The relationship between the p layer and the n layer may be reversed, so that the top layer and bottom layer may be of p-InP while the selective diffused portion may be of n-InP. As the light receiving sections should be formed accurately on the designed optical paths of the individual wavelengths, it is necessary to precisely align the light receiving surface at which light is refracted with the reflection surface at which light is reflected.

The inclined surface of a light receiving surface 101 and a recessed surface 401 of the reflection surface, which have been precisely aligned by photolithography using a double sided aligner, are formed by wet etching. A reflection film 202 is formed on the recessed surface 401. An SiO₂ film formed by CVD is suitable for the reflection film 202. Besides SiO₂, the reflection film 202 may be formed of an insulator having a lower refractive index than InP, such as SiN, resin, air or N₂, or a metal having a high reflectance, such as Au or Cu.

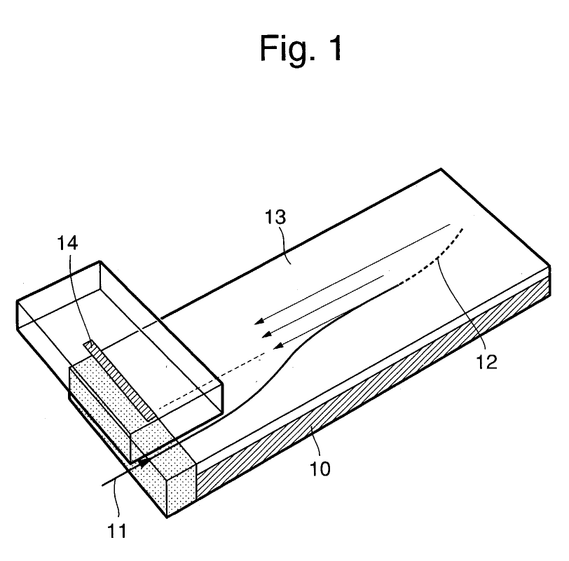

When 1.3-μm light and 1.5-μm band light are input to the light receiving surface 101 on one side of the device in FIG. 1, the refraction angle varies due to the difference between the refraction angles on the semiconductor substrate corresponding to the individual wavelengths. Let us consider a case where a resin with a reflectance of 1.4 seals around the device of the embodiment. In case where the angle of the light receiving surface 101 is 54° with respect to the bottom, the incident angle becomes 36° and the optical path varies due to the wavelength-originated difference in refraction angle.

Next, the individual lights are reflected at the reflection film 202 on the recessed surface 401 and the optical paths are greatly separated from those before reflection due to the difference between the refraction angles corresponding to the individual wavelengths. The reason is that as the lights whose optical paths have been changed at the light receiving surface 101 due to the difference between their refraction angles are input to the recessed surface 401 at different angles and in different positions, the reflection angles when the lights with the respective wavelengths are reflected at the recessed surface 401 differ from each other, making the spread angle of the light of each wavelength greater. The smaller the radius of curvature of the recessed surface 401, the more noticeable this effect becomes. Therefore, the use of the recessed surface 401 facilitates the demultiplexing of light. The individual lights reflected at the reflection film 202 on the recessed surface 401 are respectively received by the 1.3-μm light receiving section 102 and the 1.5-μm band receiving section 402 on the top portion of the device.

The light receiving device of the embodiment, even with a small device size, can receive separate 1.3-μm light and 1.5-μm band light. Given that the device has a width of 50 μm and a thickness of 150 μm and the radius of curvature of the recessed surface 401 is R=30 μm, 1.3-μm light and 1.5-μm band light can be received in their light receiving positions apart from each other by 10.7 μm. If the device size is increased to make the optical paths longer, lights of wavelengths belonging to the 1.5-μm band light and close to one another at intervals of 0.8 nm can also be received in a demultiplexed fashion.

(Second Embodiment)

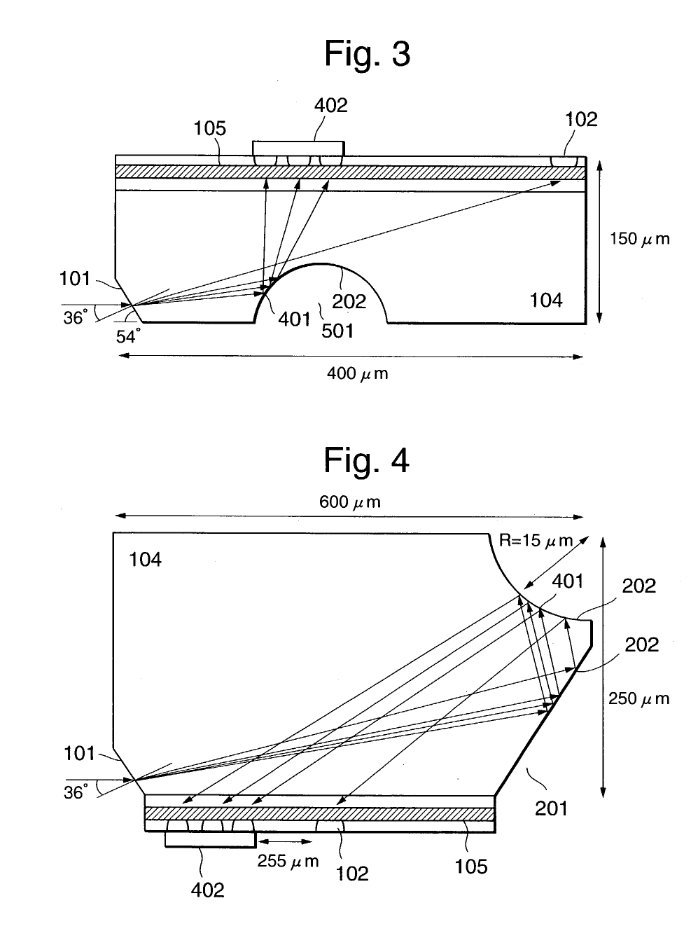

FIG. 3 presents a cross-sectional view of the second embodiment of the invention. The second embodiment is a side incident type light receiving device which has a recessed groove 501 formed in the back of the device. The reflection film 202 is formed on the recessed surface 401 of the recessed groove 501. The 1.3-μm light receiving section 102 and 1.5-μm band receiving section 402 are formed on the top portion of the device. The material for the semiconductor substrate, the structures of the light receiving sections and the method of forming the reflection film are the same as those of the first embodiment.

When lights are input to the light receiving surface 101 on one side of the device in FIG. 3, their optical paths are changed due to the wavelength-originated difference between the refraction angles. The 1.5-μm band light is reflected at the reflection film 202 on the recessed surface 401 of the recessed groove 501 and is received by the 1.5-μm band receiving section 402 on the top portion of the device. Because there is no recessed surface 401 on the optical path for 1.3-μm light, the 1.3-μm light is not reflected at the reflection surface and is received directly by the 1.3-μm light receiving section 102 the top portion of the device. As a result, the distance between the 1.3-μm light and the 1.5-μm band light is increased, thus facilitating separation of the 1.3-μm light from the 1.5-μm band light and ensuring separation of lights of the individual wavelengths close to the 1.5-μm band.

(Third Embodiment)

FIG. 4 presents a cross-sectional view of the third embodiment of the invention. The embodiment is a side incident type light receiving device which has a reflection surface 201 formed opposite to the light receiving surface 101 and has the recessed surface 401 formed above the reflection surface 201. The reflection surface 201 is an inclined surface and the reflection film 202 is formed on the reflection surface 201. The reflection film 202 is also formed on the recessed surface 401. The 1.3-μm light receiving section 102 and the 1.5-μm band receiving section 402 are formed at the back of the device.

When lights are input to the light receiving surface 101 on one edge of the device in FIG. 4, their optical paths are changed due to the wavelength-originated difference between the refraction angles. The individual lights are all reflected at the reflection film 202 on the reflection surface 201 and are input to the recessed surface 401. In case where an insulator is used for the reflection film 202, total reflection occurs. Because the angles and positions at which the individual lights are input to the recessed surface 401 differ from each other, the reflection angles at the recessed surface 401 also differ from each other, thus separating their optical paths greatly from those before reflection. The lights that have been reflected at the reflection film 202 on the recessed surface 401 are received by the 1.3-μm light receiving section 102 and the 1.5-μm band receiving section 402 formed at the back of the device. In the embodiment, it is easy to provide long optical paths even for a small device size and it is possible to separate the light receiving position of the 1.3-μm light receiving section 102 from the light receiving position of the 1.5-μm band receiving section 402 by 255 μm.

(Fourth Embodiment)

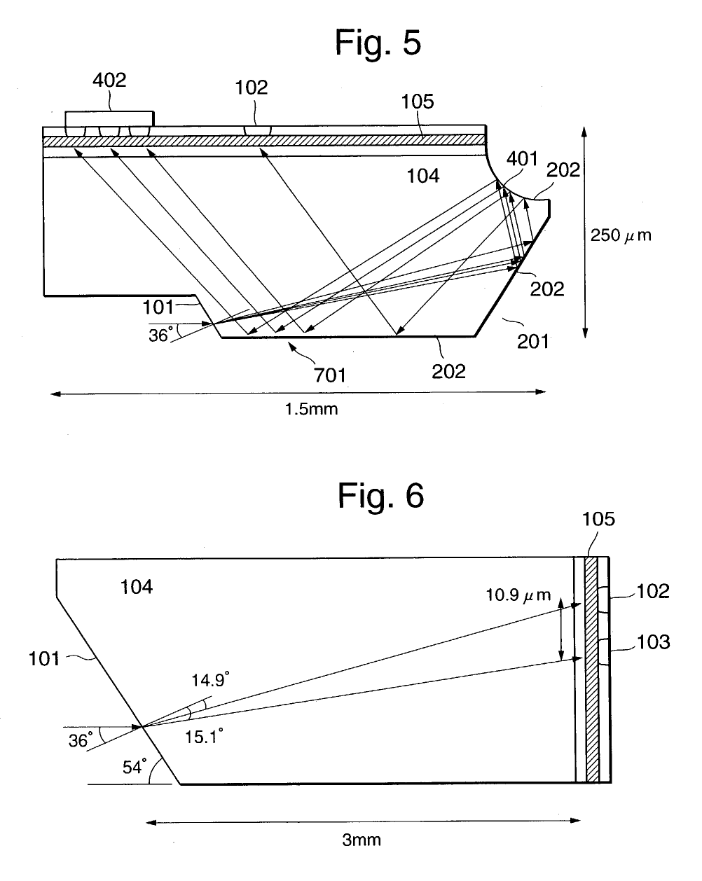

FIG. 5 presents a cross-sectional view of the fourth embodiment of the invention. The embodiment is a side incident type light receiving device which has a reflection surface 201 formed opposite to the light receiving surface 101, the recessed surface 401 opposing the reflection surface 201 and a reflection surface 701 formed at the back of the device. The reflection surface 201 takes the form of an inclined surface and the reflection film 202 is formed on the reflection surface 201. The reflection film 202 is also formed on the recessed surface 401. The reflection film 202 is also formed on the reflection surface 701. The 1.3-μm light receiving section 102 and the 1.5-μm band receiving section 402 are formed on the top portion of the device.

When lights are input to the light receiving surface 101 on one side of the device in FIG. 5, their optical paths are changed due to the wavelength-originated difference between the refraction angles. The individual lights are all reflected at the reflection film 202 on the reflection surface 201 and are input to the recessed surface 401. Because the angles and positions at which the individual lights are input to the recessed surface 401 differ from each other, the reflection angles at the recessed surface 401 also differ from each other, thus separating their optical paths greatly from those before reflection. The lights that have been reflected at the reflection film 202 on the recessed surface 401 are input to the reflection surface 701 formed at the back of the device. The lights that are reflected at the reflection film 202 on the reflection surface 701 are respectively received by the 1.3-μm light receiving section 102 and the 1.5-μm band receiving section 402 formed on the top portion of the device. Adding the reflection surface 701 to the third embodiment can keep long optical paths even when the semiconductor substrate 104 is thin. This is useful in case where the semiconductor substrate 104 cannot be made thick for the sake of convenience of the fabrication steps.

(Fifth Embodiment)

FIG. 6 presents a cross-sectional view of the fifth embodiment of the invention. The embodiment is a back the 1.3-μm light receiving section 102 and a 1.55-μm receiving section 103 formed at the back of the device.

When lights of 1.3 μm and 1.55 μm are input to the light receiving surface 101 in FIG. 6, the refraction angles differ from each other due to the difference between the reflection angles of the semiconductor substrate so that the refraction angle for 1.3 μm light becomes 14.9° and the refraction angle for 1.55 μm light becomes 15.1°. When the semiconductor substrate has a thickness of about 3 mm, the 1.3-μm light and 1.55-μm light can be received separately for the light receiving positions for the 1.3-μm light and 1.55-μm light are separated by a distance of 10.9 μm.

(Sixth Embodiment)

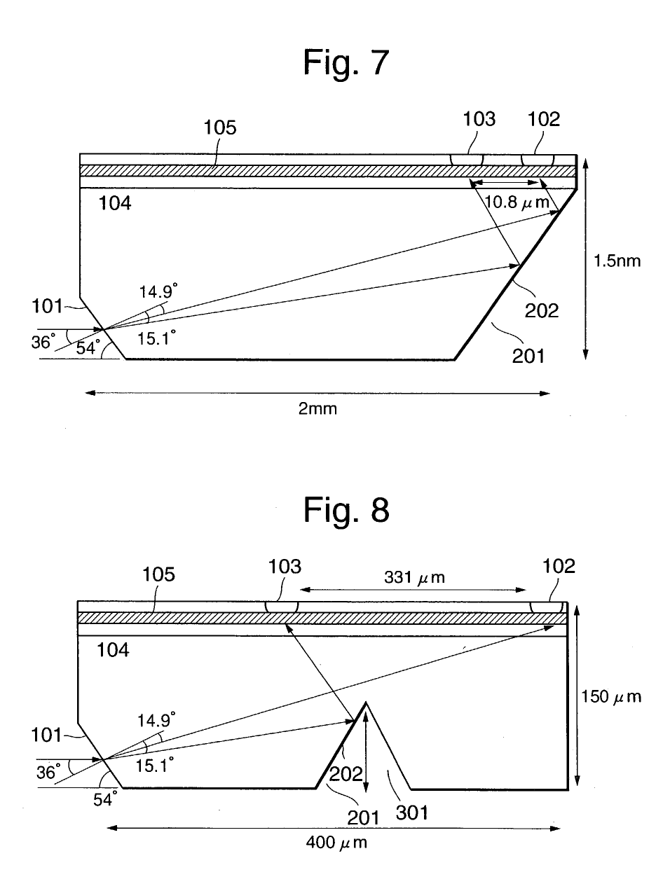

FIG. 7 presents a cross-sectional view of the sixth embodiment of the invention. The embodiment is a side incident type light receiving device which has the reflection surface 201 formed opposite to the light receiving surface 101. The reflection surface 201 takes the form of an inclined surface and the reflection film 202 is formed on the reflection surface 201. The 1.3-μm light receiving section 102 and the 1.5-μm band receiving section 402 are formed on the top portion of the device.

When lights are input to the light receiving surface 101 on one side of the device in FIG. 7, their optical paths are changed due to the wavelength-originated difference between the refraction angles. The individual lights are all reflected at the reflection film 202 on the reflection surface 201 and are received by the 1.3-μm light receiving section 102 and the 1.55-μm receiving section 103 on the top portion of the device. When the device has a width of 2 mm and a thickness of 1.5 mm, the light receiving positions for the 1.3-μm light and 1.55-μm light are separated by a distance of 10.8 μm, thus ensuring separate reception of the 1.3-μm light and 1.55-μm light.

(Seventh Embodiment)

FIG. 8 presents a cross-sectional view of the seventh embodiment of the invention. The embodiment is a side incident type light receiving device which has a V groove 301 formed at the back of the device and uses the inclined surface of the V groove 301 as the reflection surface 201. The reflection film 202 is formed on the reflection surface 201. The 1.3-μm light receiving section 102 and the 1.5-μm band receiving section 402 are formed on the top portion of the device.

When lights are input to the light receiving surface 101 on one side of the device in FIG. 8, their optical paths are changed due to the wavelength-originated difference between the refraction angles. The 1.55-μm light is reflected at the reflection film 202 on the reflection surface 201 which is a mesa surface and is received by the 1.55-μm receiving section 103 on the top portion of the device. Because there is no reflection surface on the optical path for 1.3-μm light, the 1.3-μm light is not reflected and is received directly by the 1.3-μm light receiving section 102 the top portion of the device. When the device has a width of 400 μm and a thickness of 150 μm and the depth of the V groove 301 is set to 19.1 μm, the light receiving positions for the 1.3-μm light and 1.55-μm light can be separated by a distance of 331 μm.

Although the foregoing description has been given of preferred embodiments of the fabrication method for a semiconductor device according to the invention referring to the accompanying drawings, the invention is not limited to those embodiments. It should be apparent to those skilled in the art that the invention may be modified or altered in various forms without departing from the spirit or scope of the invention and those modifications and alterations should belong to the scope of the invention.

Although the foregoing description has been given of the case where demultiplexed input lights are received after being reflected once, twice or three times, the invention is not limited to this particular case. Increasing the number of reflections is effective in that the optical paths in the device can be made longer and the input lights may be received after reflection of more than three times.

What is claimed is:

1. A semiconductor light receiving device to which light having a plurality of wavelengths is input from a side direction and which comprises:
a light receiving surface which is formed on an inclined surface crossing a back and sides of a semiconductor substrate, to which said light having said plurality of wavelengths is input and which demultiplexes said light having said plurality of wavelengths in accordance with differences among refraction angles corresponding to said wavelengths;
a reflection film, formed opposite to said light receiving surface, for reflecting at least a part of said light having said plurality of wavelengths; and
a plurality of light receiving sections, formed on said semiconductor substrate, for receiving light for each of said plurality of wavelengths.

2. The semiconductor light receiving device according to claim 1, wherein said reflection film is formed on a recessed surface crossing said back and sides of said semiconductor substrate and reflects all demultiplexed lights of said light having said plurality of wavelengths to cause said all demultiplexed lights to reach said light receiving sections respectively.

3. The semiconductor light receiving device according to claim 1, wherein said reflection film is formed on a recessed surface in said back of said semiconductor substrate and reflects only a desired demultiplexed light of said light having said plurality of wavelengths to cause said desired demultiplexed light to reach an associated one of said light receiving sections.

4. The semiconductor light receiving device according to claim 1, wherein said reflection film is formed on said inclined surface crossing said back and sides of said semiconductor substrate and reflects all demultiplexed lights of said light having said plurality of wavelengths to cause said all demultiplexed lights to reach said light receiving sections respectively.

5. The semiconductor light receiving device according to claim 1, wherein said reflection film is formed on a V-shaped groove of said semiconductor substrate and reflects only a desired demultiplexed light of said light having said plurality of wavelengths to cause said desired demultiplexed light to reach an associated one of said light receiving sections.

6. A semiconductor light receiving device to which light having a plurality of wavelengths is input from a side direction and which comprises:
a light receiving surface which is formed on an inclined surface crossing a back and sides of a semiconductor substrate, to which said light having said plurality of wavelengths is input and which demultiplexes said light having said plurality of wavelengths in accordance with differences among refraction angles corresponding to said wavelengths;
a first reflection film, formed opposite to said light receiving surface and on an inclined surface crossing said back and sides of said semiconductor substrate, for reflecting said light having said plurality of wavelengths;
a second reflection film, formed opposite to said first reflection film and on a recessed surface crossing a top and said sides of said semiconductor substrate, for reflecting reflected light from said first reflection film; and
a plurality of light receiving sections, formed on said back of said semiconductor substrate, for receiving light for each of said plurality of wavelengths.

7. A semiconductor light receiving device to which light having a plurality of wavelengths is input from a side direction and which comprises:
a light receiving surface which is formed on an inclined surface crossing a back of a semiconductor substrate, to which said light having said plurality of wavelengths is input and which demultiplexes said light having said plurality of wavelengths in accordance with differences among refraction angles corresponding to said wavelengths;
a first reflection film, formed opposite to said light receiving surface and on an inclined surface crossing said back and sides of said semiconductor substrate, for reflecting said light having said plurality of wavelengths;
a second reflection film, formed opposite to said first reflection film and on a recessed surface crossing a top and said sides of said semiconductor substrate, for reflecting reflected light from said first reflection film;
a third reflection film, formed on said back of said semiconductor substrate, for reflecting reflected light from said second reflection film; and
a plurality of light receiving sections, formed on said top of said semiconductor substrate, for receiving light for each of said plurality of wavelengths.

8. A semiconductor light receiving device to which light having a plurality of wavelengths is input from a backside direction and which comprises:
a light receiving surface which is formed on an inclined surface crossing a back and sides of a semiconductor substrate, to which said light having said plurality of wavelengths is input and which demultiplexes said light having said plurality of wavelengths in accordance with differences among refraction angles corresponding to said wavelengths; and
a plurality of light receiving sections, formed on said semiconductor substrate, for receiving light for each of said plurality of wavelengths.
